(19) United States
(12) Patent Application Publication
(10) Pub. No.: US 2005/0141732 A1
(43) Pub. Date: Jun. 30, 2005

(54) Amplifying apparatus

(76) Inventor: Kazuya Miyamoto, Tokorozawa -shi (JP)

Correspondence Address: Richard P. Berg;c/o LADAS & PARRY, Suite 2100, 5670 Wilshire Boulevard, Los Angeles, CA, 90036-5679, US

(21) Appl. No.: 11/001,671

(22) Filed: Nov. 30, 2004

(30) Foreign Application Priority Data
Dec. 1, 2003 (JP) P2003-401310

(51) Int. Cl. H03G 5/00; H03G 9/00

(52) U.S. Cl. 381/101; 84/600; 381/102

(57) ABSTRACT

An amplifying apparatus S is provided which includes a digital attenuator 2 for digitally controlling the output level of an output signal Sₒᵤₜ, a variable power source 1 for controlling the power source electricity supplied for control over the output level, and a feedback portion 4 for reducing the distortion included in the output signal Sₒᵤₜ, and which further includes a microcomputer 7 for, at least when the output level is reduced by the variable power source 1, controlling the feedback portion 4 so as to reduce a feedback amount of the feedback portion 4 gradually by using a plurality of preset fixed values. The amplifying apparatus is for reducing an output level by control over power source electricity and digital control and reducing distortion by a feedback process, and the apparatus is capable of securely reducing the output level as well as reducing the distortion while improving a signal-to-noise ratio of a tone signal to be outputted.

### BACKGROUND OF THE INVENTION

1. Field of the Invention

The present invention relates to an amplifying apparatus, and in particular, to the amplifying apparatus for controlling an output level of a tone signal including voice or music and outputting it to outside.

2. Description of the Related Art

In general, in the case of producing a sound from a speaker unit in an audio system, an amplifying apparatus (so-called amplifier) included in that audio system controls an output level of a tone signal to be outputted to an input terminal of the speaker unit, and outputs it to the input terminal and thereby controls an amount of the sound produced from the speaker unit.

Here, as for conventional methods for controlling the output level described above, a method where the output level is controlled by controlling power source electricity used on amplifying the tone signal in a final output stage to the speaker unit, and another method where the output level of the tone signal is directly and digitally controlled in a stage preceding the final output stage have been developed. the output level of the tone signal in a stage preceding the final output stage. In this regard, a latter digital control of the output level is adopted for reasons such as simple circuitry, easy handling of the signal itself (circuit design) or a to-noise property.

In the conventional amplifying apparatus, the output level has been controlled by combining the two methods described above. To be more specific, in the case of reducing the output level (in other words, narrowing down the sound produced from the speaker unit) for instance, the output level is reduced as much as possible first by controlling the power source electricity to be supplied. And after reducing it to an extent of being no longer reducible by controlling the power source electricity, it is further reduced by digitally controlling the output level so as to render the output level indefinitely closer to zero as a result (See, JP2001-202696A and JP2003-122396, for example).

Apart from the control of the output level described above, the conventional audio system also uses a method of feeding back the tone signal in the stage preceding the final output stage to the tone signal in a further preceding stage in order to reduce an acoustic distortion included in the tone signal outputted to the speaker unit.

Conventionally, the apparatus has a configuration in which control of the output level by combined use of the two methods described above is overlapped with reduction in distortion by the feedback so as to reduce the distortion and output the tone signal while exerting digital control with the simple circuitry.

In the case of reducing an output level of the tone signal and thereby reducing an amount of produced sound in the configuration of the conventional amplifying apparatus, the reduction in the output level and the reduction in the distortion described above are concurrently performed. In this case, if the feedback amount is maintained in a state before the reduction in the output level in spite of the reduced output level, a balance between the output level of the tone signal and the feedback amount is lost so that it may actually lead to an increase in the distortion and degradation of sound quality.

Thus, it is necessary to reduce the feedback amount continuously in accordance with continuous reduction in the output level of the tone signal. Given the present circumstances, however, it is technically difficult to reduce the feedback amount continuously in the case of digitally feeding back the tone signal after having its output level controlled in the amplifying apparatus digitally controlling the output level. Therefore, the feedback amount is normally a preset fixed value under the present state of the art.

As the feedback amount is fixed, a lower limit to the reduction in the output level due to control over power source electricity has to be the fixed value on the reduction in the output level. In the case of reducing the output level further than that lower limit, there is no other choice than to rely on the digital control of the output level.

However, in the case where an amount of reduction in a digital output level is higher than a certain value, for example, when reducing (narrowing down) the output level to low-order 5 bits or less on digitally controlling the output level with 24 bits, the output level after the reduction to that area becomes not much different from a level of noise originally included in the tone signal. Consequently, there arises a new problem that the tone signal to be originally outputted gets buried in that noise and a signal-to-noise ratio (hereafter, merely referred to as an S/N ratio (Signal/Noise) ratio) is reduced.

### SUMMARY OF THE INVENTION

Thus, the present invention has been implemented in consideration of the problems, and an object thereof is to provide the amplifying apparatus for reducing the output level by the control over the power source electricity and digital control and reducing the distortion by the feedback process, the apparatus capable of securely reducing the output level as well as reducing the distortion while improving the S/N ratio of the tone signal to be outputted.

To solve the problems, an amplifying apparatus according to the present invention comprises a digital output control device such as a digital attenuator for digitally controlling an output level of a tone signal; a power control device such as a variable power source for controlling power source electricity supplied for control of the output level; and a feedback device such as a feedback portion for feeding back the tone signal of which output level is controlled and thereby reducing a distortion included in the tone signal, and which apparatus outputs the tone signal of which output level is controlled to outside, wherein the apparatus further comprise a control device such as a microcomputer for, when the output level is reduced by at least one of the power control device or the digital output control device, controlling the feedback device so as to reduce a feedback amount of the feedback device in stages by using a plurality of preset fixed values.

### BRIEF DESCRIPTION OF THE DRAWINGS

FIG. 1 is a block diagram showing an overview configuration of an amplifying apparatus according to a first embodiment of the present invention;

FIG. 2 is a flowchart showing a control process of an output level performed in the amplifying apparatus according to the first embodiment of the present invention; and

FIG. 3 is a flowchart showing the control process of the output level performed in the amplifying apparatus according to a second embodiment.

### DETAILED DESCRIPTION OF THE PREFERRED EMBODIMENTS

Next, the detailed description of the preferred embodiments of the present invention will be described with referred to the annexed drawings. The embodiments described below are the embodiments in the case of applying the present invention to an amplifying apparatus (so-called main amplifier or the like) used for an output stage and so on in a general audio system.

### (I) First Embodiment

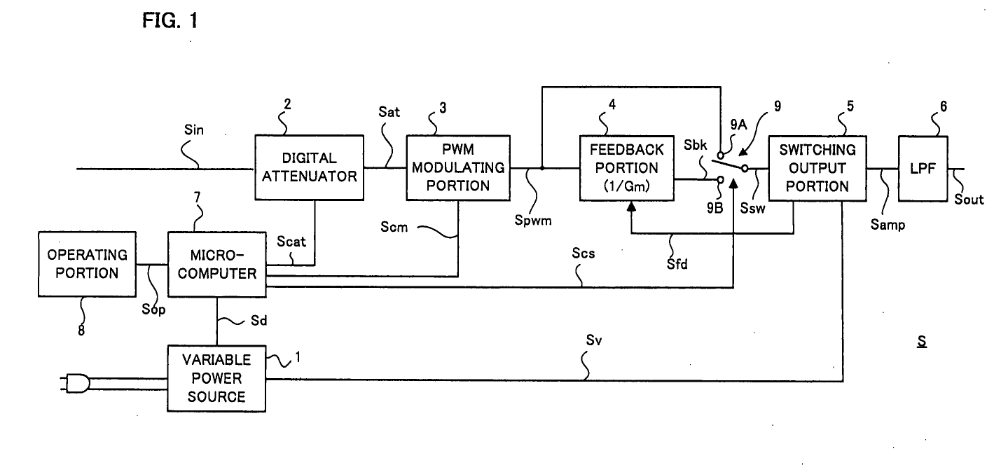

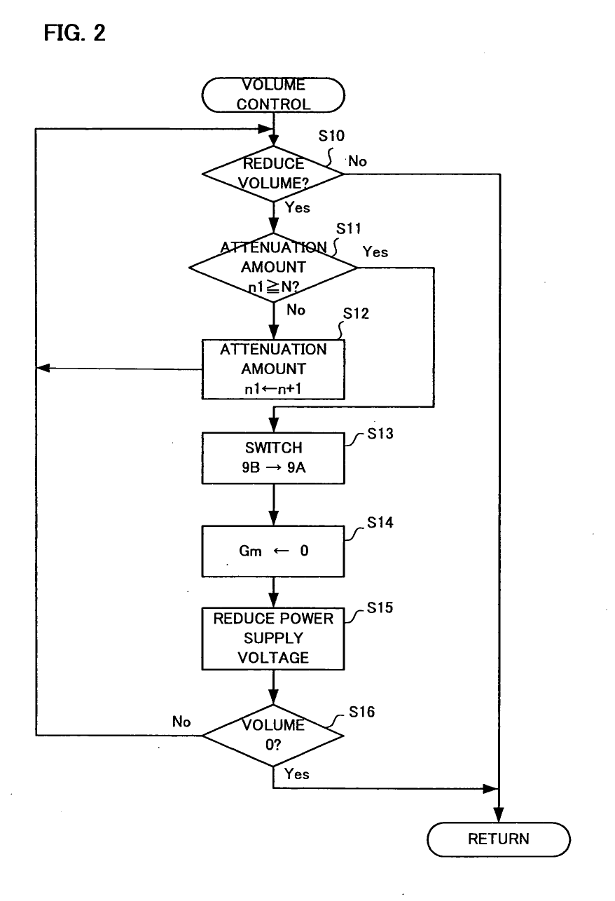

To begin with, a first embodiment of the present invention will be described by using FIGS. 1 and 2. FIG. 1 is a block diagram showing an overview configuration of an amplifying apparatus according to the first embodiment. FIG. 2 is a flowchart showing control of an output level of a tone signal exerted in the amplifying apparatus.

As shown in FIG. 1, an amplifying apparatus S according to the first embodiment is comprised of, for example, a variable power source 1 as a power source control device to be connected to a 100 Volts AC power source for domestic use, a digital attenuator 2 as a digital output control device, a PWM (Pulse Width Modulation) modulating portion 3, a feedback portion 4 as a feedback device, a switching output portion 5, an LPF (Low Pass Filter) 6, a microcomputer 7 as a control device, an operating portion 8 having a volume control knob (not shown) described later, and a switch 9 comprising a terminal 9A connected to the PWM modulating portion 3 and a terminal 9B connected to the feedback portion 4.

Next, overall operation will be described.

First, the variable power source 1 is connected to the 100 Volts AC power source for domestic use, and supplies a variable voltage signal Sᵥ to the switching output portion 5 based on a control signal S_{d} from the microcomputer 7.

A tone signal Sᵢₙ outputted with an output level controlled by the amplifying apparatus S is inputted to the digital attenuator 2 first, and then the signal is subjected to a processing for controlling the output level digitally by the digital attenuator 2 based on a control signal S_{cat} from the microcomputer 7. The tone signal Sᵢₙ having its output level digitally controlled is outputted to the PWM modulating portion 3 as a level control signal Sₐₜ.

Next, the PWM modulating portion 3 performs a preset PWM modulating process to the level control signal Sₐₜ in accordance with a control signal S_{cm} from the microcomputer 7 and outputs it to the feedback portion 4 and terminal 9A as a modulation signal S_{pwm}.

Next, the feedback portion 4 of which feedback rate is a preset steady value Gₘ performs a feedback process using a feedback signal S_{fd} to the modulation signal S_{pwm} by subtracting from the modulation signal S_{pwm} a signal acquired by multiplying the output level of the feedback signal S_{fd} from the switching output portion 5 by the feedback rate Gₘ so as to generate a feedback process signal S_{bk} and output it to the terminal 9B.

The switch 9 switches the terminal 9A or 9B in accordance with a control signal S_{cs} from the microcomputer 7, and outputs the signal from either terminal to the switching output portion 5 as a switch signal S_{sw}.

Thus, the switching output portion 5 outputs the switch signal S_{sw} to the feedback portion 4 as the feedback signal S_{fd}, and amplifies or attenuates the switch signal S_{sw} to the output level corresponding to the variable voltage signal Sᵥ from the variable power source 1 so as to output it to the LPF 6 as an amplification signal Sₐₘₚ.

The LPF 6 eliminates noise components and soon included in a high frequency band of the amplification signal Sₐₘₚ, generates an output signal Sₒᵤₜ and outputs it to a not-shown speaker unit and so on outside so as to produce a sound.

To implement the operations of the above components, the microcomputer 7 generates the control signals S_{cat}, S_{cm}, S_{sc} and S_{d} and outputs them to the corresponding components so that the operations of the contents operated by a user in the operating portion 8 will be implemented in accordance with an operation signal Sₒₚ from the operating portion 8.

Next, an output level reduction process (that is, a volume narrowing process) of the output signal Sₒᵤₜ according to the first embodiment performed in the amplifying apparatus S having the above-mentioned configuration will be described by using FIG. 2. The output level reduction process shown in FIG. 2 is performed as a part of an output level control process performed in the amplifying apparatus S according to the first embodiment.

In a stage for starting the output level reduction process shown in FIG. 2, the switch 9 is switched to the terminal 9B side by the control signal S_{cs} from the microcomputer 7, and the output level control process by functions of the digital attenuator 2 and variable power source 1 and a distortion reduction process by a function of the feedback portion 4 are concurrently performed.

As shown in FIG. 2, in the output level reduction process according to the first embodiment, it is first checked by the operation signal Sₒₚ whether or not the operation for reducing the output level of the output signal Sₒᵤₜ has been performed in a not-shown volume control knob of the operating portion 8 (step S10). If the operation has not been performed (step S10; NO), it returns as-is to the control process at the original output level. If the operation has been performed (step S10; YES), it is checked next whether or not an attenuation amount (that is, an output level reduction amount) n₁ in the digital attenuator 2 by the operation of the volume control knob is a preset threshold N or more (step S11).

If the attenuation amount is not the threshold N or more (step S11; NO), the attenuation amount in the digital attenuator 2 is increased by one step in accordance with an operation amount of the volume (step S12), and the process returns to the step S10 so as to repeat the steps S10 to S12 for a further volume operation.

If the attenuation amount by the digital attenuator 2 is the threshold N or more (step S11; YES), the switch 9 is switched next from the current terminal 9B to 9A in accordance with the control signal S_{cs} from the microcomputer 7. Thus, the feedback process in the feedback portion 4 will no longer be involved in the output level control of the tone signal Sᵢₙ (output signal Sₒᵤₜ).

A concrete value of the above-mentioned threshold N is preset as a design matter correspondingly to performance desired as the amplifying apparatus S. To be more specific, it is preset based on the output level desired on outputting the output signal Sₒᵤₜ to the outside, an S/N ratio which the output signal Sₒᵤₜ should have on the outputting and a distortion factor allowed to the output signal Sₒᵤₜ on the outputting.

After prohibiting the feedback portion 4 from fulfilling its function, the feedback rate of the feedback portion 4 is “0” (step S14). Next, while maintaining the current attenuation amount of the digital attenuator 2, the output level reduction thereafter is implemented by reducing the value of the variable voltage signal Sᵥ from the variable power source 1 (step S15).

It is checked in accordance with the operation signal Sₒₚ thereafter whether or not the volume has been operated to “0,” that is, to a lower limit (step S16). In the case where it has not reached the lower limit yet (step S16; NO), it returns to the step S10 to continue the output level reduction process described above correspondingly to the operation amount of the volume. In the case where the volume has been operated to the lower limit (step S16; YES), the output level reduction process according to the first embodiment is finished as-is so as to return to the original output level control process.

As described above, according to the operation of the amplifying apparatus S of the first embodiment, the output signal Sₒᵤₜ is outputted without the feedback portion 4 functioning when the output level reduction amount of the output signal Sₒᵤₜ becomes less than the threshold N. Therefore, the distortion is reduced in the stage in which the output level reduction amount is small, and the output level can be reduced just by the variable power source 1 when the output level reduction amount is large. Thus, it is possible to securely reduce the output level in a state of a good S/N ratio.

The threshold N is preset based on the output level on outputting the output signal Sₒᵤₜ to the outside, the S/N ratio which the output signal Sₒᵤₜ should have on the outputting and the distortion factor allowed to the output signal Sₒᵤₜ on the outputting. Therefore, it is possible to securely reduce the output level of the output signal Sₒᵤₜ in the state of a good S/N ratio according to the performance desired about the amplifying apparatus S.

Furthermore, the function of the feedback portion 4 is switched by switching the switch 9, and so it is possible, with a simple configuration, to control whether or not the function of the feedback portion 4 is fulfilled.

### (II) Second Embodiment

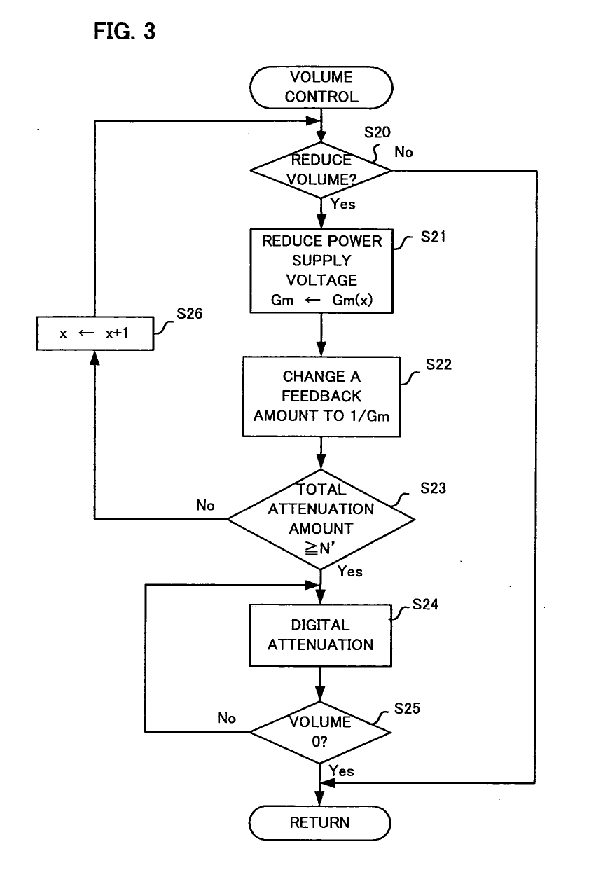

Next, a second embodiment as another embodiment of the present invention will be described by using FIGS. 1 and 3. FIG. 3 is a flowchart showing the operation of the amplifying apparatus according to the second embodiment.

The above first embodiment described the case of prohibiting the feedback portion 4 from fulfilling its function when the output level of the output signal Sₒᵤₜ is low. While the feedback portion 4 can be switched only in two stages of whether or not to fulfill its function according to the first embodiment, the second embodiment described below is the embodiment in the case of switching the feedback portion 4 to multistage using fixed values with preset feedback rates.

Furthermore, the configuration of the amplifying apparatus according to the second embodiment is the same as that of the amplifying apparatus S according to the first embodiment except that a plurality of preset feedback rates Gm(x) (it is set up so that the larger the value of a natural number x is, the lower the feedback rate becomes) are stored in the feedback portion 4 according to the first embodiment and the feedback rates Gm(x) are switched by control from the microcomputer 7. Therefore, a detailed description thereof will be omitted.

As shown in FIG. 3, in the output level reduction process according to the second embodiment, it is first checked by the operation signal Sₒₚ whether or not the operation for reducing the output level of the output signal Sₒᵤₜ has been performed in a not-shown volume of the operating portion 8 (step S20). If the operation has not been performed (step S20; NO), it returns as-is to the control process at the original output level. If the operation has been performed (step S20; YES), it reduces the value of the variable voltage signal Sᵥ from the variable power source 1 to reduce the output level based on this volume operation, and lowers the feedback rate of the feedback portion 4 by one stage (steps S21, S22).

And it is checked whether or not the attenuation amount of the variable power source 1 is the preset threshold N′ or more (step S23).

If the attenuation amount is not the threshold N′ or more (step S23; NO), a parameter x indicating the feedback rate of the feedback portion 4 is increased by one stage (step S26) to return to the step S20 so as to further continue the output level reduction by the variable power source 1.

If the attenuation amount by the variable power source 1 is the threshold N′ or more (step S23; YES), while maintaining the current attenuation amount of the variable power source 1, the output level reduction thereafter is implemented by reducing the attenuation amount of the digital attenuator 2 (step S24).

A concrete value of the above-mentioned threshold N′ is preset as the design matter correspondingly to the performance desired as the amplifying apparatus S as in the case of the first embodiment.

It is checked based on the operation signal Sₒₚ thereafter whether or not the volume has been operated to “0,” that is, to the lower limit (step S25). In the case where it has not reached the lower limit yet (step S25; NO), it continues the output level reduction process by the digital attenuator 2 described above correspondingly to the operation amount of the volume (step S24). In the case where the volume has been operated to the lower limit (step S25; YES), the output level reduction process according to the second embodiment is finished as-is so as to return to the original output level control process.

The method of the output level reduction according to the second embodiment described above is different from the method of the output level reduction according to the first embodiment described above in that the output level is first reduced by the control of the variable power source 1 (refer to the step S21 in FIG. 3) and then is reduced by the digital attenuator 2 (refer to the step S24 in FIG. 3) (to be more precise, according to the method of the output level reduction of the first embodiment, the output level is first reduced by the digital attenuator 2 (refer to the step S11 in FIG. 2.) and then is reduced by the control of the variable power source 1 (refer to the step S15 in FIG. 2). This is because it is possible, by reducing the output level as much as possible by the output level reduction process of the variable power source 1, to ignore influence exerted on the S/N ratio in terms of acoustic sense (practical use in other words) even if extremely minute output level reduction is performed thereafter by the digital attenuator 2.

To be more specific, if the amount of the output level reduced by using the digital attenuator 2 is small, it is not so disadvantageous from a viewpoint of improvement in the S/N ratio. Therefore, as to the present invention, it is possible, by reducing the output level as much as possible first with the variable power source 1, to reduce the output level thereafter by using the digital attenuator 2.

As described above, according to the operation of the amplifying apparatus S of the second embodiment, a feedback amount of the feedback portion 4 is reduced in stages by using a plurality of fixed values Gm(x) when the output level of the output signal Sₒᵤₜ is reduced by the variable power source 1. Therefore, the feedback rate Gm(x) is gradually reduced while reducing the distortion in a stage of a small amount of the output level reduction. And it is possible to match the amount of reduction to the feedback amount to be in the stage of the low output level and continue the output level reduction by the variable power source 1 to the low output level so as to securely reduce the output level in the as-is state of a good S/N ratio.

As the plurality of preset feedback rates Gm(x) are stored in the feedback portion 4 in order to control the feedback rate by switching among them, it is possible to control the feedback portion 4 in fulfilling its function in stages with the simple configuration.

The above-mentioned embodiments described the cases of applying the present invention to the amplifying apparatus applied to an audio system. It is also possible, however, to apply the present invention widely to the amplifying apparatuses for concurrently controlling the output level by control over a power supply voltage, directly controlling the digital output level and reducing the distortion by a feedback method in various apparatuses accompanied by control over the output level of sound.

The entire disclosure of Japanese Patent Application No. 2003-401310 filed on Dec. 1, 2003 including the specification, claims, drawings and summary is incorporated herein by reference in its entirety.

1. An amplifying apparatus, comprising:
a digital output control device for digitally controlling an output level of a tone signal;
a power control device for controlling power source electricity supplied for control of the output level;
a feedback device for feeding back the tone signal of which output level is controlled and thereby reducing a distortion included in the tone signal, wherein the tone signal of which output level is controlled is output to the outside from the amplifying apparatus; and
a control device for, at least when the output level is reduced by the power control device, controlling the feedback device so as to reduce a feedback amount of the feedback device gradually by using a plurality of preset fixed values.

2. The amplifying apparatus according to claim 1, wherein the control device controls the feedback device to prohibit it from fulfilling its feedback function and output the tone signal when an amount of reduction becomes less than a preset threshold.

3. The amplifying apparatus according to claim 2, wherein the threshold is preset based on:
the output level on outputting the tone signal to the outside;
a signal-to-noise ratio which the tone signal should have on the outputting; and
a distortion factor allowed to the tone signal on the outputting.

4. The amplifying apparatus according to claim 2, wherein the control device includes:
a switch device for excluding the feedback device from a transmission path of the tone signal; and
a switch control device for switching the switch device to exclude the feedback device from the transmission path when the amount of reduction becomes less than the threshold.

5. The amplifying apparatus according to claim 3, wherein the control device includes:
a switch device for excluding the feedback device from a transmission path of the tone signal; and
a switch control device for switching the switch device to exclude the feedback device from the transmission path when the amount of reduction becomes less than the threshold.
